(19) United States
(12) Patent Application Publication
(10) Pub. No.: US 2011/0000538 A1
(43) Pub. Date: Jan. 6, 2011

(54) NON-IMAGING SOLAR CONCENTRATOR REFLECTOR FOR PHOTOVOLTAIC CELLS

(76) Inventor: Christopher Rush, Forestville, CA (US)

Correspondence Address: Christopher Rush, 7475 Poplar Dr., Forestville, CA, 95436, US

(21) Appl. No.: 12/829,790

(22) Filed: Jul. 2, 2010

Related U.S. Application Data
(60) Provisional application No. 61/223,184, filed on Jul. 6, 2009.

(51) Int. Cl. H01L 31/0232

(52) U.S. Cl. 136/256

(57) ABSTRACT

The invention discloses a non-imaging reflecting surface optimized for concentrating solar energy onto a high efficiency solar cell. It provides for accurate mapping of solar radiation from the reflector to the cell. Additionally it provides for using only that portion of the surface that participates in the radiation transfer and it creates substantially uniform radiation intensity on the cell surface. The uniformity applies to both the spectral and the intensity distribution of the radiation on the cell. The reflecting surface is an off-axis parabolic surface trimmed to include only ray intercepts that travel to the solar cell surface. The solar cell is located off-focus so that rays from the reflector intercept the cell surface according to a predetermined mapping.

This application claims the benefit of U.S. Provisional Application No. 61/223,184 filed Jul. 6, 2009.

### FIELD OF THE INVENTION

This invention relates to devices for concentrating solar energy for conversion to electrical power. More specifically it relates to the conversion of solar flux by the use of a new class of photovoltaic semiconductors known as multi junction cells. These cells offer significantly higher conversion efficiencies over existing silicon cells in that they extract energy from several bands of the solar spectrum. The conversion efficiency is further enhanced by increasing the solar energy flux density on the receiver cells. Such cells are typically more expensive to fabricate than ordinary silicon photovoltaic cells so commercially practical devices require the concentration of sunlight. Cost savings are achieved by increasing the ratio of common materials such as aluminum, glass or plastic, to expensive semiconductor materials.

### BACKGROUND OF THE INVENTION

In the field of solar concentrators, a common design is to use rotationally symmetric conic surfaces, such as paraboloids (FIG. 1), to increase the power density delivered to cells. Another type of concentrator employs refracting components such as lenses or, more commonly, Fresnel lenses (FIG. 2) to concentrate the light energy. Solar concentration ratios in the range of 100 to 2,000 times the normal irradiance of the sun are required to bring the higher cost of multi junction cells into commercial parity with existing silicon photovoltaic cells. Multi junction photocells require, for optimum conversion efficiency, a uniform distribution of concentrated light intensity across the entire area of the receiver surface. Additionally, their performance is degraded if the local distribution of spectral wavelengths is non-uniform. It is a well known failing of concentrator devices that spectral uniformity is lost with designs that depend on refraction. This is a property of the Fresnel concentrator designs represented by (FIG. 2) Uniformity of flux intensity is lost with the use of focusing refracting and reflecting concentrators. One of the properties of axially symmetric concentrators, which include lenses and parabolic surfaces of rotation, is that they produce an irradiance pattern having a circular profile. The irradiance pattern is an approximately Gaussian intensity distribution on the receiving surface. Since receivers are usually rectangular, either the corners are not illuminated or there is light spillage beyond the active region of the receiver. U.S. Pat. No. 5,153,780 (Jorgensen et. al.) and U.S. Pat. No. 6,620,995 (Vasylev et.al.) disclose a concentrating reflector that produces uniform energy flux on multi junction receivers, but the drawback with these devices is that the irradiance profiles are circular. These phenomena lead to severe degradation of conversion efficiency. FIG. 3 shows yet another design for concentrators. This is called a cassegrain system. It achieves reduced sensitivity to alignment error but it does not solve the problem of the non-uniform irradiance distribution on the receiver cell. Another type of concentrator often employed for solar concentration is the non-imaging concentrator an example of which is the compound parabolic concentrator or CPC (FIG. 4). This device is disclosed in U.S. Pat. No. 3,923,381 (Winston). As solar concentrators, CPCs and other devices of the same type have the disadvantage of possessing a long aspect ratio and a non-uniform flux output when concentrating substantially parallel solar rays. Attempts to overcome the disadvantages of the paraboloids, Fresnel lenses or non-imaging concentrators include the addition of secondary and tertiary optical components. The principle drawback to these designs is that each additional surface that the radiation encounters before it reaches the receiver entails losses due to scatter, absorption, and reflection. Achieving uniform irradiance can involve multiple surface interactions between solar rays and optical surfaces. In addition to the added cost for these components, secondary and tertiary optical components are subjected to elevated energy concentration levels. This leads to faster deterioration and material breakdown over time.

Thus there is a need for solar concentrators that produce high concentration ratios while at the same time providing for both spectral and intensity uniformity. There is further a need for solar concentrators that produce high concentration ratios that do not suffer from the optical losses due to multiple interactions between solar rays and component surfaces. There is further a need for solar concentrators that produce high concentration ratios that do not suffer from the added cost of fabricating, and aligning additional optical components. And there is yet further a need for solar concentrators that produce high concentration ratios that also provide for uniform illumination that matches the shape of the receiver. There is additionally an advantage to providing a solar concentrator with a small aspect ratio. Such concentrators provide several advantages: The first is they minimize material usage because the focusing support structure is short. They have increased resistance to deformation under wind loading, and the low f# focal properties provide for reduced sensitivity to misalignment error. Thus there is a need for a solar concentrator having a small aspect ratio with a consequently low short focal length optical property.

### OBJECTS OF THE INVENTION

The invention discloses a concentrating optical reflector differing from prior art in the fact that the concentrator is constructed specifically for the task of transferring solar radiation from the reflecting surface to the solar cell while providing edge to edge irradiance uniformity both in terms of intensity and in terms of wavelength distribution. As shown in FIGS. 7A, 7B, and 7C, the cell is tilted so that the cell diagonal line is parallel to the parabolic axis. The receiving cell is also placed off-focus, for example, in front of the focal point, so that rays converge at a point beyond the plane of the cell. The off-axis paraboloid surface is trimmed to eliminate all areas of the surface that do not contribute to the concentrating function. In this way the objective of achieving uniform illumination that matches the shape of the receiver is achieved. The cell is placed off-focus so that reflected rays map to different regions of the cell. Thus the invention achieves the object of achieving high concentration and spectral and intensity uniformity. Since the invention does not utilize any secondary or tertiary optical components the invention achieves the objective of lower cost for fabrication and alignment as well. Further, it achieves the objective of avoiding the efficiency losses associated with solar rays interacting with multiple surfaces because it uses only one reflecting surface. The invention takes as the starting surface a parabolic curve, such that he focus is located substantially coincident with the opening aperture. This geometry produces the minimum aspect ratio with the consequent low f# optical and shortest possible cell support structure.

### SUMMARY OF THE INVENTION

It has been found that the object of this invention may be realized by providing a non-imaging solar concentrating reflector consisting of an optical configuration comprising a multi junction photovoltaic cell located off-focus and facing a substantially paraboloid off-axis surface of minimum aspect ratio. The paraboloid surface is trimmed by planes defined by the parabolic focal point and the vertices of the cell corners.

### BRIEF DESCRIPTION OF THE DRAWINGS

FIG. 1 (Prior Art) Shows a profile view and ray trace for the parabolic reflector concentrator.

FIG. 2 (Prior Art) Shows a profile view and ray trace for the Fresnel lens concentrator.

FIG. 3 (Prior Art) Shows a profile view and ray trace for the cassegrain reflector concentrator employing secondary and tertiary components to achieve irradiance uniformity.

FIG. 4 (Prior Art) Shows a profile view and ray trace for the Compound parabolic reflector concentrator (CPC).

FIG. 5 Shows a 3D chart according to a ray trace simulation displaying the solar energy distribution pattern that is commonly produced by the parabolic reflector, the Fresnel lens, or the cassegrain concentration optical designs.

FIG. 6 Shows an isobar chart according to a ray trace simulation displaying the solar energy distribution pattern that is commonly produced by the parabolic reflector, the Fresnel lens, or the cassegrain concentration optical designs.

FIG. 7A is a perspective view of a paraboloid surface showing the starting point for the construction of the reflecting surface.

FIG. 7B is a perspective view of the reflecting surface of FIG. 7A cut according to two cutting planes established by the parabolic focus and the corner vertices of the solar cell.

FIG. 7C is a perspective view of the reflecting surface of FIG. 7A showing the final shape after it has been cut according to the cutting planes described in FIG. 7B

FIG. 7D Shows a projected view of the reflecting surface as seen from the direction of the sun. Color coded sub-regions of the solar cell are shown reflected in the image. This provides a map of the photon trajectories as they strike the reflector and travel to the cell.

FIG. 8 Shows a 3D chart according to a ray trace simulation displaying the solar energy distribution pattern that is produced by the reflector of the present invention.

FIG. 9 Shows an isobar chart according to a ray trace simulation displaying the solar energy distribution pattern that is produced by the reflector of the present invention.

FIG. 10 Shows a perspective view of an alternate embodiment of the reflecting surface. The slightly outer convex edges have been trimmed to be straight lines.

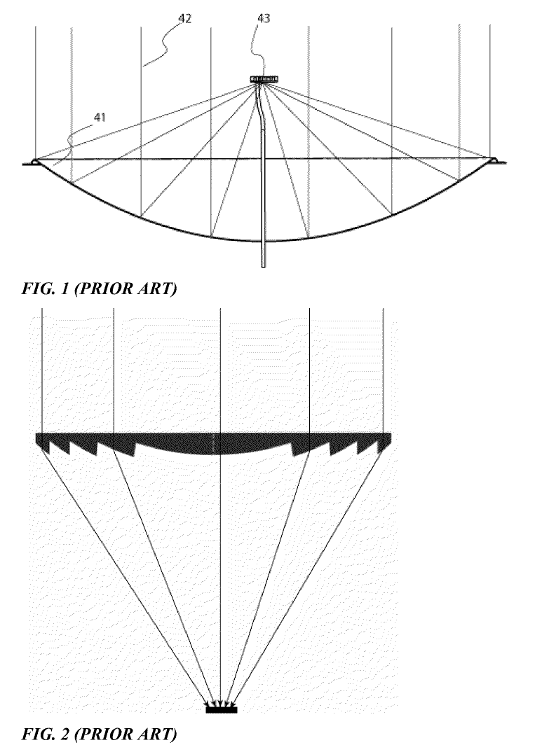

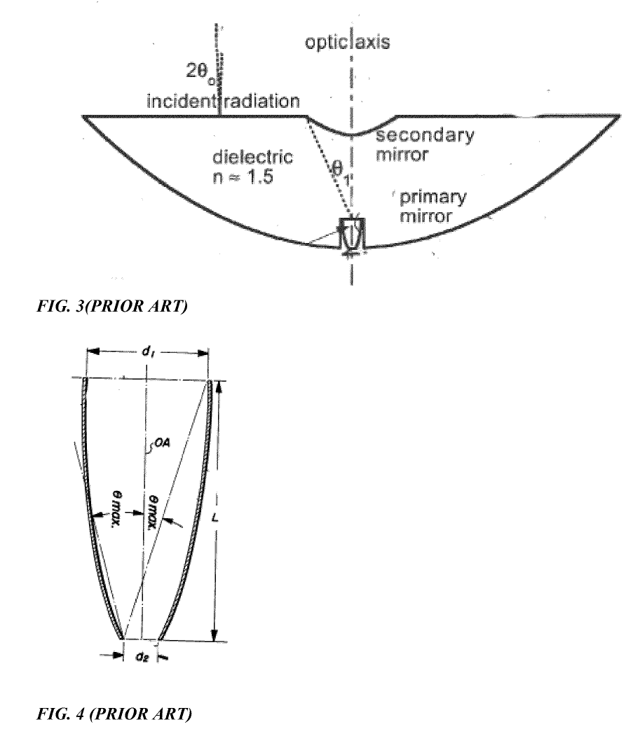

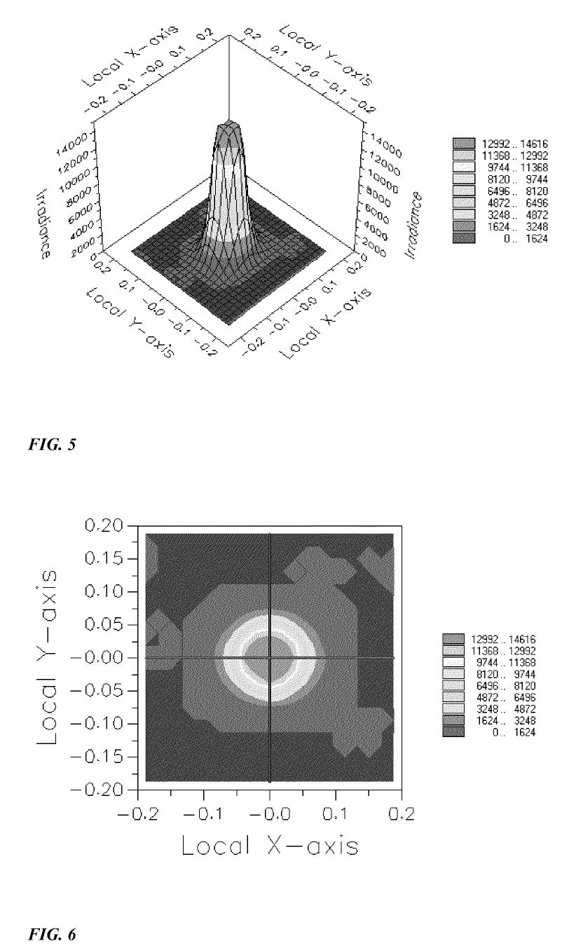

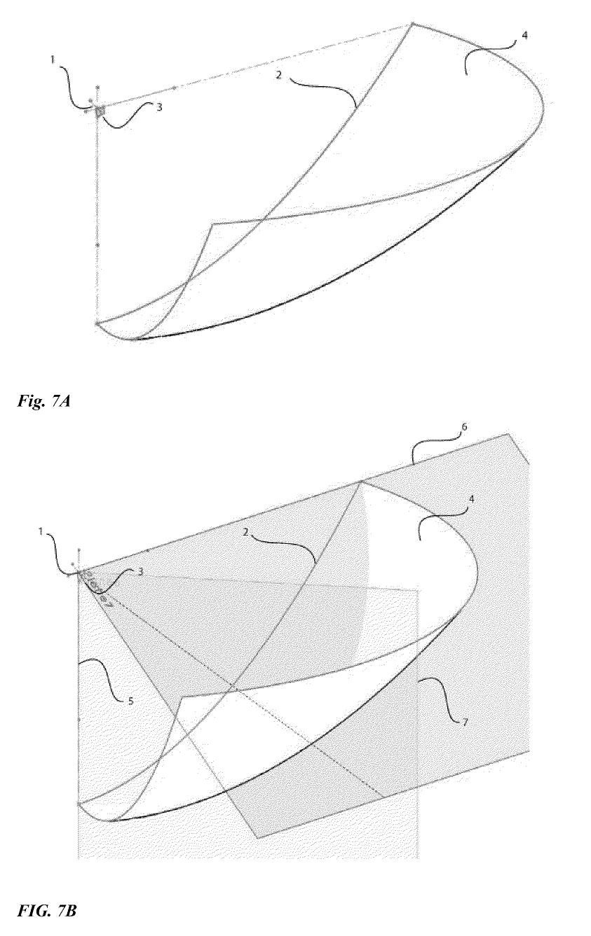

### DETAILED DESCRIPTION OF THE INVENTION

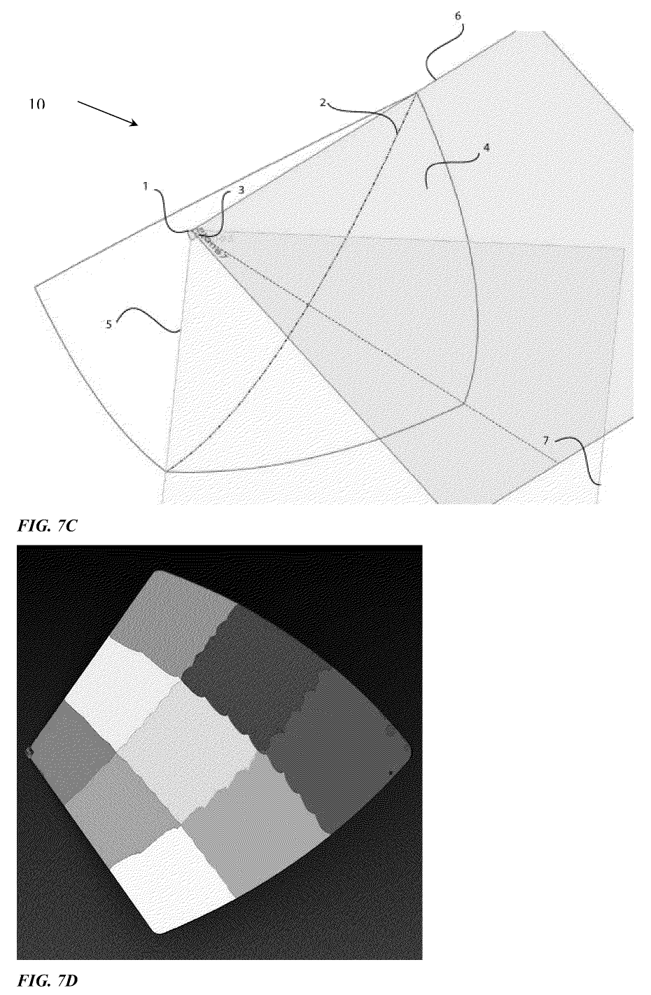

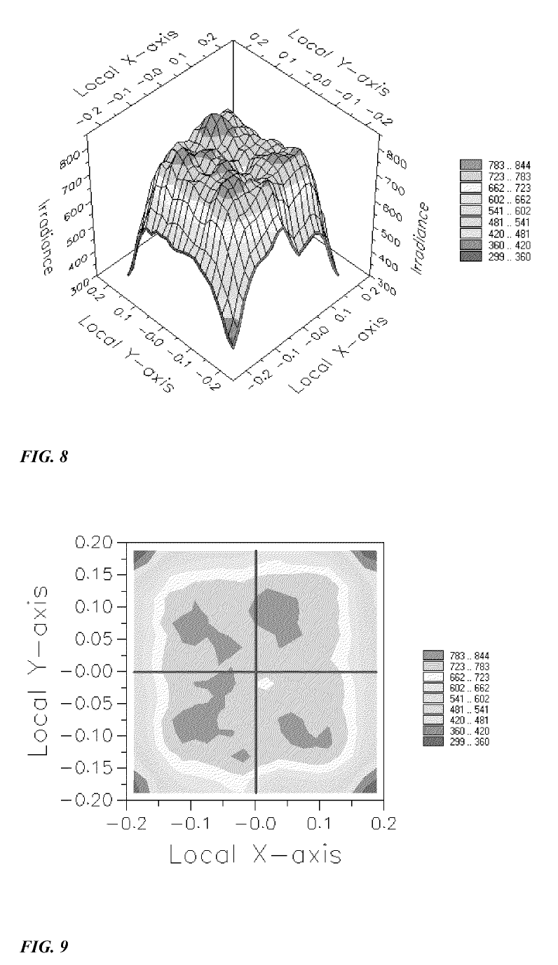

Referring to FIG. 7A the reflective surface (4) is a substantially parabolic surface. It is created as a sweep of parabolic curve (2) about axis (5). In one embodiment the parabolic curve used to generate the surface is created so that the focus (1) is located on the same plane as the reflector aperture. The focal distance is chosen such that the planar projection of the trimmed surface is many times larger than the area of the receiving cell. The photovoltaic cell is turned so that its diagonal line is in the same plane as the parabolic surface's optic axis. The plane of the cell is further tilted at an angle of approximately 45 degrees with respect to the optic axis (5). The parabolic surface is trimmed by planes defined according to the following method: Referring to FIG. 7B, trimming planes are established defined by the three points comprising the parabolic focus (1), and two of the vertices of the solar cell (3) corners. FIG. 7B shows the parabolic surface (4) is cut along the intersection of the paraboloid surface and the above described planes (6) and (7). In FIG. 7C the reflector (10) is shown in its final shape. It is a four sided figure possessing slightly convex edges. It is symmetric about the plane defined by the diagonal of the solar cell and the optic axis. FIG. 7D shows the radiation mapping. The solar cell sub-regions are artificially shaded and a ray-tracing rendering of the reflector taken from the perspective of the sun shows the radiation distribution on the cell surface.

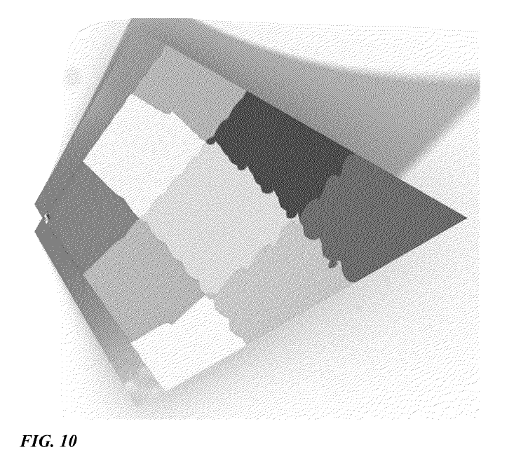

Alternative embodiments of this invention may be constructed that are within the scope of the invention. One such alternative embodiment further trims the convex edges of the reflecting surface so that their projections are straight lines. This shape is shown in FIG. 10. This geometric change may be applied in order to fit the reflectors more tightly into an array if the slight loss of optical efficiency is acceptable.

Another embodiment allows for the initial generating parabolic curve to deviate slightly from a true parabola. This can be applied in order to further enhance the irradiance uniformity of the design.

I claim:

1. A Solar concentrating optical reflector comprising
a. a trimmed part of a substantially paraboloid reflective surface of rotation possessing an axis of rotation and a focus point
b. having edges defined as the intersection of said reflective surface and each of the four planes defined by the three points consisting of the said reflective surface focus point and two adjacent corners of a rectangular photovoltaic cell oriented so that the diagonal of said cell is parallel to the rotation axis of the said reflective surface, and is also oriented so that the cell's active area is near to, but not coincident with, the focal point of said reflective surface and where the cell's active area is substantially facing the reflective surface
whereby solar optical energy reflected by said surface arrives at a photovoltaic cell active area with substantially uniform intensity.

2. A Solar concentrating optical reflector comprising
a. a trimmed part of a substantially paraboloid reflective surface of rotation possessing an axis of rotation and a focus point
b. having edges defined as the projection of four straight lines, two of which are directed radially from the focus of said reflective surface at an angle of approximately 120 degrees, and two straight lines at an angle of approximately 60 degrees symmetrically disposed about the bisector of the first pair of lines.
c. Said surface disposed substantially facing a rectangular photovoltaic cell that has been oriented so that the diagonal of said cell is parallel to the rotation axis of the said reflective surface, and is also oriented so that the cell's active area is near to, but not coincident with, the focal point of said reflective surface
whereby solar optical energy reflected by said surface arrives at a photovoltaic cell active area with substantially uniform intensity and so adjacent reflective surfaces may be arranged so that they fit closely together.
